(19) United States
(12) Patent Application Publication
(10) Pub. No.: US 2014/0124728 A1
(43) Pub. Date: May 8, 2014

(54) RESISTIVE MEMORY DEVICE, RESISTIVE MEMORY ARRAY, AND METHOD OF MANUFACTURING RESISTIVE MEMORY DEVICE

(71) Applicant: SAMSUNG ELECTRONICS CO., LTD., Suwon-Si (KR)

(72) Inventors: Chang-jung KIM, Yongin-si (KR); Sung-ho KIM, Yongin-si (KR); Young-bae KIM, Seoul (KR); Seung-ryul LEE, Seoul (KR); U-in CHUNG, Seoul (KR)

(73) Assignee: SAMSUNG ELECTRONICS CO., LTD., Suwon-Si, Gyeonggi-Do (KR)

(21) Appl. No.: 13/836,564

(22) Filed: Mar. 15, 2013

(30) Foreign Application Priority Data
Nov. 6, 2012 (KR) 10-2012-0125085

(51) Int. Cl. H01L 27/24; H01L 45/00

(52) U.S. Cl. CPC H01L 27/2454; H01L 45/16
USPC 257/5; 257/2; 438/238

(57) ABSTRACT

A resistive memory device has a structure in which a source, a channel layer, a drain, and a resistive memory layer are sequentially formed in a particular direction, with a gate electrode formed around the channel layer. The source, channel layer, and drain may be vertically stacked on a substrate, and the gate electrode may be formed completely around the channel layer.

### CROSS-REFERENCE TO RELATED APPLICATIONS

This application claims the benefit of Korean Patent Application No. 10-2012-00125085, filed on Nov. 6, 2012 in the Korean Intellectual Property Office, the disclosure of which is incorporated herein in their entirety by reference.

### BACKGROUND

1. Field

The present disclosure relates to resistive memory devices.

2. Description of the Related Art

A semiconductor memory includes a plurality of memory cells that are connected in a circuit. In the case of a dynamic random access memory (DRAM) which is a representative semiconductor memory, a unit memory cell may be composed of one switch and one capacitor.

A DRAM has strong points in terms of high integrity and short response time. However, when power is turned off, all stored data are erased. A representative non-volatile memory device that can keep stored data when power is turned off is flash memory. Flash memory has a non-volatile characteristic unlike the volatile memory, but has a drawback in terms of low integrity and long response time when compared to the DRAM.

Examples of non-volatile memory devices that have been studied include resistance random access memory (RRAM), magnetic random access memory (MRAM), ferroelectric random access memory (FRAM), and phase-change random access memory (PRAM). An RRAM, which is a resistive memory device, uses a characteristic of changing resistance (that is, a resistance conversion characteristic) according to an applied voltage for purposes of storing data.

### SUMMARY

Example embodiments described herein include resistive memory devices having a vertical structure and resistive memory arrays.

Example embodiments described herein provide methods of manufacturing the resistive memory devices having a vertical structure. According to an example embodiment, a resistive memory device includes a source, a channel layer, a drain, and a resistive memory layer configured vertically on a substrate; a gate electrode configured around the channel layer; and an insulating layer between the channel layer and the gate electrode. The gate electrode may be configured to completely surround the channel layer.

The source, the channel layer, the drain, and the resistive memory layer may be sequentially formed on an upper surface of the substrate. The source, the channel layer, the drain, and the resistive memory layer may be vertically formed with respect to the upper surface of the substrate.

The resistive memory layer may be formed of a bipolar resistance variable material. The resistive memory layer may be formed of a transition metal oxide, and the transition metal oxide may be formed of at least one selected from the group consisting of Ni oxide, Ti oxide, Hf oxide, Zr oxide, Zn oxide, W oxide, Co oxide, Al oxide and Nb oxide.

The resistive memory layer may be formed of at least one selected from the group consisting of PrCaMnO(PCMO), CaMnO3(CMO), CaTiO3, BaTiO3, SrTiO3, KTaO3, KNbO3, and NaNbO3.

According to another example embodiment, a resistive memory array includes a plurality of the resistive memory devices described above The resistive memory array may further include a word line configured to carrier signals (e.g., power) to the gate electrode and a bit line configured to carry signals (e.g., power) to the resistive memory layer.

The resistive memory array may further include: a first interlayer dielectric (ILD) film formed between the gate electrode and the word line; and a first contact layer formed between the gate electrode and the word line.

The resistive memory array may further include: a second ILD film formed between the resistive memory layer and the bit line; and a second contact layer formed between the resistive memory layer and the bit line.

According to another example embodiment, a method of manufacturing a resistive memory device, the method including: forming a source, a channel layer, and a drain to be sequentially stacked on a substrate; forming a gate electrode around the channel layer; and forming a resistive memory layer on the drain. The source, the channel layer, and the drain may be sequentially formed in a vertical direction with respect to an upper surface of the substrate by etching a source region, a channel region, and a drain region which are formed by respectively doping a dopant in a material for forming a substrate. The gate electrode may completely surround the channel layer.

### BRIEF DESCRIPTION OF THE DRAWINGS

The above and other features and advantages of example embodiments will become more apparent by describing in detail example embodiments with reference to the attached drawings. The accompanying drawings are intended to depict example embodiments and should not be interpreted to limit the intended scope of the claims. The accompanying drawings are not to be considered as drawn to scale unless explicitly noted.

FIG. 1 is a cross-sectional view showing an embodiment of a resistive memory device.

FIG. 2 is a cross-sectional view showing an embodiment of a unit device that includes a resistive memory device.

FIGS. 3A through 9B are drawings showing operations included in an embodiment of a method of manufacturing a resistive memory device.

FIG. 10 is a schematic graph showing an operation characteristic of an embodiment of a resistive memory device.

### DETAILED DESCRIPTION OF EXAMPLE EMBODIMENTS

Detailed example embodiments are disclosed herein. However, specific structural and functional details disclosed herein are merely representative for purposes of describing example embodiments. Example embodiments may, however, be embodied in many alternate forms and should not be construed as limited to only the embodiments set forth herein.

Accordingly, while example embodiments are capable of various modifications and alternative forms, embodiments thereof are shown by way of example in the drawings and will herein be described in detail. It should be understood, however, that there is no intent to limit example embodiments to the particular forms disclosed, but to the contrary, example embodiments are to cover all modifications, equivalents, and alternatives falling within the scope of example embodiments. Like numbers refer to like elements throughout the description of the figures.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

It will be understood that when an element is referred to as being “connected” or “coupled” to another element, it may be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between”, “adjacent” versus “directly adjacent”, etc.).

In the drawings, it is understood that the thicknesses of layers and regions may be exaggerated for clarity. It will also be understood that when a layer is referred to as being “on” another layer or substrate, it can be directly on the other layer or substrate or intervening layers may also be present. Like reference numerals in the drawings denote like elements, and thus their description will not be repeated. As used herein, the term “and/or” includes any and all combinations of one or more of the associated listed items. Expressions such as “at least one of,” when preceding a list of elements, modify the entire list of elements and do not modify the individual elements of the list.

The terminology used herein is for the purpose of describing particular embodiments only and is not intended to be limiting of example embodiments. As used herein, the singular forms “a”, “an” and “the” are intended to include the plural forms as well, unless the context clearly indicates otherwise. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

FIG. 1 is a cross-sectional view showing an embodiment of a resistive memory device 100 which includes a substrate 10, a source 11a formed on the substrate 10, and a channel layer 12, a drain 11b, and a resistive memory layer 15 formed on the drain 11b on a region of the source 11a.

A gate electrode 14 may be formed on a peripheral region of the channel layer 12, and also the gate electrode 14 may be formed on a peripheral region of the source 11a or the drain 11b. An insulating layer 13 may be formed between the channel layer 12 and the gate electrode 14. Also, the insulating layer 13 may be formed between the source 11a and the drain 11b and the gate electrode 14. Optionally, the location of the source 11a and the drain 11b may be reversed.

In the resistive memory device 100 according to the current example embodiment, an all-around gate structure in which the gate electrode 14 is formed to surround the channel layer 12 is formed, and thus further effective gate control may be realized. Also, according to the current example embodiment, the resistive memory device 100 may be formed to have a vertical type memory device structure in which the source 11a, the channel layer 12, the drain 11b, and the resistive memory layer 15 are sequentially formed with respect to an upper surface of the substrate 10. In this way, in the illustrative case where resistive memory device 100 has a 1T(transistor)-1R(resistance) memory structure, the length of the channel layer 12 may not be formed too short, and as a result a short channel effect that may occur when a ultra-small transistor is formed may be prevented.

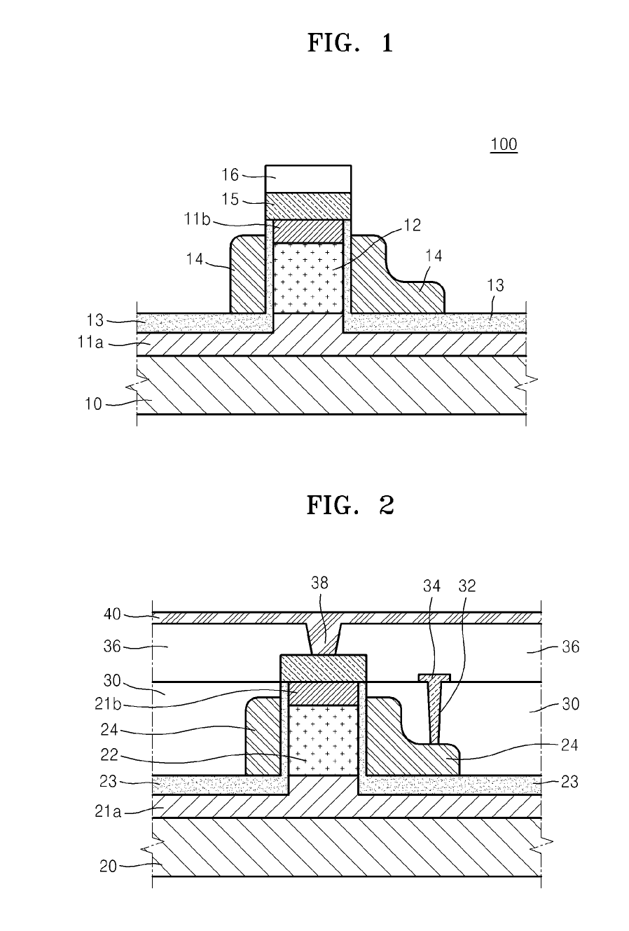

FIG. 2 is a cross-sectional view showing an example embodiment of a unit device that includes a resistive memory device. As shown, this structure includes an electrode structure through which a voltage may be applied to a gate and a memory resistive layer.

More specifically, referring to FIG. 2, the resistive memory device may include a source 21a, a channel layer 22, a drain 21b, and a resistive memory layer 25 sequentially formed in a vertical direction on a region of a substrate 20. A gate electrode 24 having a structure that surrounds laterals sides of the channel layer 22 may be formed on a peripheral region of the channel layer 22, and also, the gate electrode 24 may be formed on peripheral regions of the source 21a and the drain 21b. The gate electrode 24 may be formed to surround the lateral sides of the channel layer 22. An insulating layer 23 may be formed between the channel layer 22 and the gate electrode 24, and the may also be formed between the source 21a and the drain 21b and the gate electrode 24. Optionally, the locations of the source 21a and the drain 21b may be reversed.

A first interlayer dielectric (ILD) film 30 may be formed on a peripheral region of the gate electrode 24, and a word line WL 34 through which power may be applied to the gate electrode 24 may be formed on the first ILD film 30. The gate electrode 24 and the word line WL 34 may be electrically connected via a first contact layer 32. Also, a second ILD film 36 may be formed on the resistive memory layer 25 and the first ILD film 30, and a bit line BL 40 through which power may be applied to the resistive memory layer 25 may be formed on the second ILD film 36. The resistive memory layer 25 and the bit line 40 may be electrically connected via a second contact layer 38.

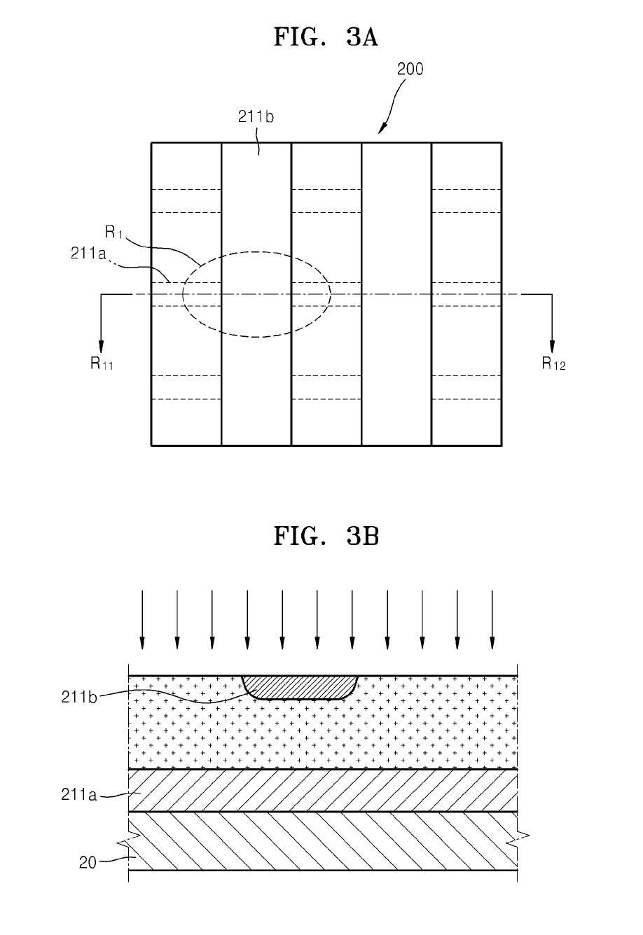

The word line WL 34 and the bit line 40 respectively may extend in first and second directions, and the direction of the word line WL 34 may differ from that of the bit line 40, e.g., may be perpendicular to or otherwise cross each other. The resistive memory device having the structure shown in FIG. 2 may be a resistive memory device that includes a resistive memory array having an array structure, which will be described below in relation to an example embodiment of a method of manufacturing the resistive memory device shown with reference to FIGS. 3A through 9B.

Examples of materials that may be included in each layer of the resistive memory device will be described.

The substrates 10 and 20 may be formed of any material used for forming general electronic devices, for example, may be a Si substrate, a SiC substrate, a glass substrate, or a GaN substrate. For example, the substrates 10 and 20 may be Si (bulk) or polysilicon to which a p-type dopant or an n-type dopant is doped.

The sources 11a and 21a and the drains 11b and 21b may be a conductive material, or may be a region of the substrates 10 and 20 doped with a dopant, for example, the sources 11a and 21a and the drains 11b and 21b may be first dopant regions or second doped regions doped with a p-type dopant or an n-type dopant. For example, the sources 11a and 21a and the drains 11b and 21b may be Si (bulk) or polysilicon in which a p-type dopant or an n-type dopant is doped.

The gate electrodes 14 and 24, the first contact layer 32, the second contact layer 38, the word line WL 34, and the bit line 40 may be formed of a conductive material of at least one selected from the group consisting of a meta, an alloy, a conductive metal oxide, a conductive metal nitride, and a conductive polymer, for example, may be formed of at least one selected from the group consisting of Al, Au, Cu, Co, Zr, Zn, W, Ir, Ru, Pt, Ti, Hf, TiN, and indium-tin-oxide (ITO).

The channel layers 12 and 22 may be formed of a channel material generally used in semiconductor devices, for example, the channel layers 12 and 22 may be Si (bulk) or polysilicon in which a p-type dopant or an n-type dopant is doped. If the sources 11a and 21a and the drains 11b and 21b are doped with an n-type dopant, the channel layers 12 and 22 may be doped with a p-type dopant, and if the sources 11a and 21a and the drains 11b and 21b are doped with a p-type dopant, the channel layers 12 and 22 may be doped with an n-type dopant.

The insulating layers 13 and 23, the first ILD film 30, and the second ILD film 36 may be formed of an insulating material, for example, Si oxide or Si nitride.

The resistive memory layers 15 and 25 may be formed of a material having a resistance conversion characteristic, that is, the resistance of which changes according to an applied voltage, for example, a bipolar resistance conversion material, such as a transition metal oxide or an oxide having a perovskite structure. The transition metal oxide used for forming the resistive memory layers 15 and 25 may be at least one selected from the group consisting of Ni oxide, Ti oxide, Hf oxide, Zr oxide, Zn oxide, W oxide, Co oxide, Al oxide, and Nb oxide. The oxide having a perovskite structure may be at least one selected from the group consisting of PrCaMnO (PCMO), CaMnO3 (CMO), CaTiO3, BaTiO3, SrTiO3, KTaO3, KNbO3, and NaNbO3.

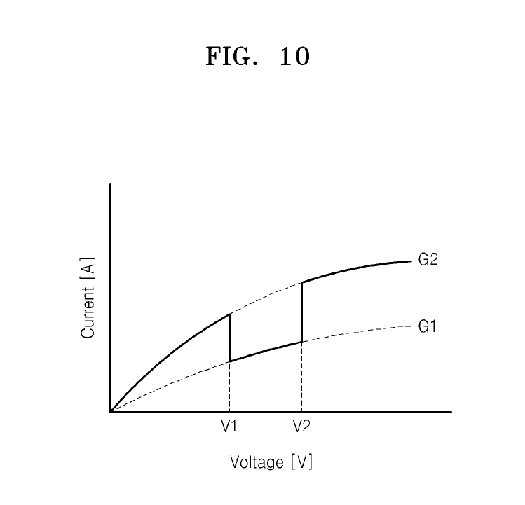

An operation characteristic of the resistive memory device according to an example embodiment is described with reference to FIG. 10. The horizontal axis of FIG. 10 indicates a voltage applied to both the resistive memory layers 15 and 25 and the vertical axis indicates a value of a current that flows through the resistive memory layers 15 and 25.

Referring to FIG. 10, when a voltage being applied to the resistive memory layers 15 and 25 is gradually increased from 0V, the current value increases as shown in a graph G2 in FIG. 10 in proportion to the applied voltage. However, when a voltage greater than V1 is applied, the current value decreases due to the increase in the resistance of the resistive memory layers 15 and 25. When a voltage is applied in a range from V1 to V2, the value of the current that flows through the resistive memory layers 15 and 25 increases as shown in a graph G1 in FIG. 10. When a voltage greater than V2 is applied to the resistive memory layers 15 and 25, the resistance is suddenly reduced, and thus, the current value follows the graph G2.

According to a magnitude of a voltage that is applied to the resistive memory layers 15 and 25 in a range greater than V1, the electrical characteristic of the resistive memory layers 15 and 25 affects the electrical characteristic of the resistive memory layers 15 and 25 when a voltage smaller than V1 is applied to the resistive memory layers 15 and 25 after the voltage in a range greater than V1 is applied thereto, which will be described below.

After applying a voltage in a range from V1 to V2 to the resistive memory layers 15 and 25, when a voltage smaller than V1 is re-applied, values of current that flows through the resistive memory layers 15 and 25 is measured as shown in the graph G2. However, after applying a voltage greater than V2 to the resistive memory layers 15 and 25, when a voltage smaller than V1 is re-applied to the resistive memory layers 15 and 25, values of current as shown in the graph G2 are measured. In this manner, the electrical characteristic of the resistive memory device is affected according to the magnitude of a voltage applied to the resistive memory layers 15 and 25 in a voltage range greater than V1.

Hereinafter, an example embodiment of a method of manufacturing a resistive memory device is described with reference to FIGS. 3A through 9B. The resistive memory device may be manufactured by using a physical vapor deposition (PVD) method, a chemical vapor deposition (CVD) method or an atomic vapor deposition (ALD) method, but is not limited thereto.

More specifically, FIGS. 3A and 3B are drawings showing an example of a process of injecting a dopant for forming a source and a drain. FIG. 3A is a plan view, and FIG. 3B is a cross-sectional view taken along the line R11-R12 of a region R1 of FIG. 3A.

Referring to FIGS. 3A and 3B, a first dopant region 211a and a second dopant region 211b are formed by doping an n-type dopant or a p-type dopant with respect to a substrate material 200, for example, Si (bulk) or polysilicon. A doping depth of the dopant may be controlled by controlling a doping energy in a doping process. The locations of the first and second dopant regions 211a and 211b may be determined in consideration of a length of a channel layer to be formed. Optionally, in order to form the channel layer, a dopant having a polarity different from that of the first and second dopant regions 211a and 211b may be doped in a region between the first and second dopant regions 211a and 211b.

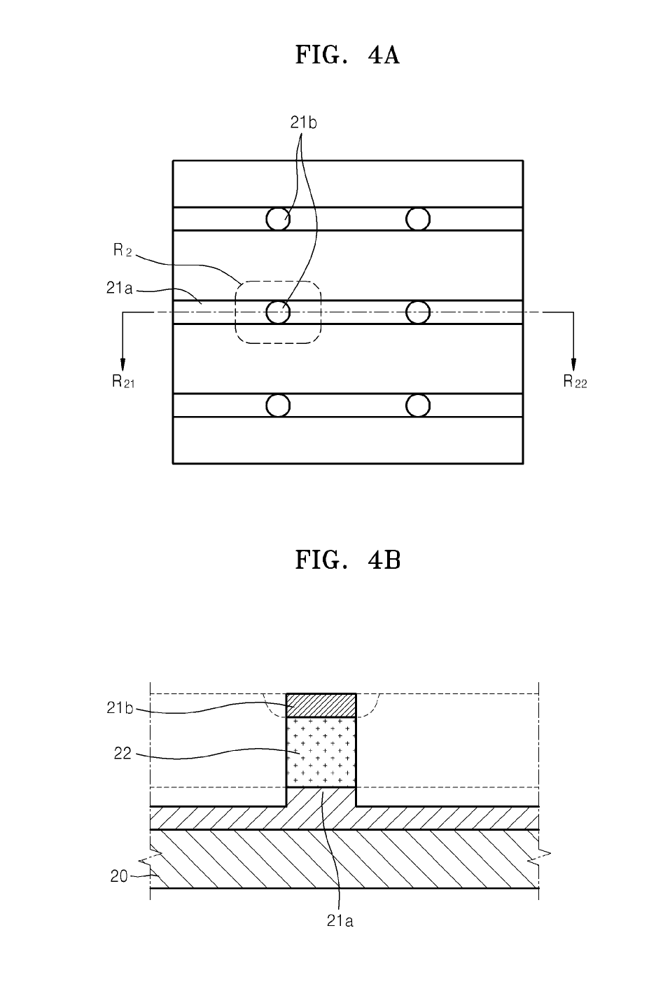

FIGS. 4A and 4B are drawings showing an example of an etching process for forming the source, the drain, and the channel layer. FIG. 4A is a plan view, and FIG. 4B is a cross-sectional view taken along the line R21-R22 of a region R2 of FIG. 4A.

Referring to FIGS. 4A and 4B, a source 21a, a channel layer 22, and a drain 21b are formed on the substrate 20 through an etching process. When the etching process is performed, a fin shape is formed by the channel layer 22 and the drain 21b protruding in a region of the substrate 20 on which the source 21a is formed. In FIG. 4A, the channel layer 22 and the drain 21b have a circular cross-section. However, the channel layer 22 and the drain 21b may have an oval cross-section, a polygonal cross-section, or another cross-sectional shape.

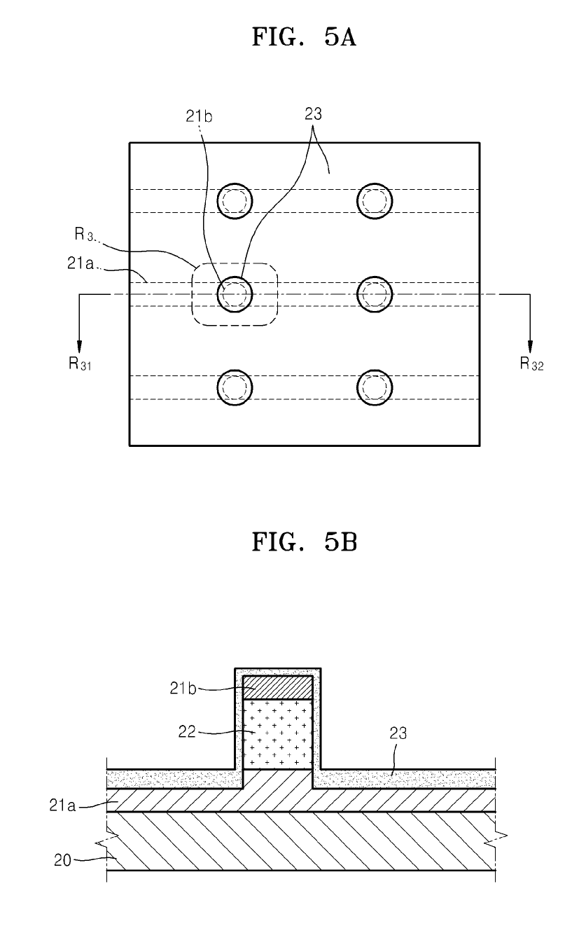

FIGS. 5A and 5B are drawings showing an example of a process of forming the insulating layer 23. FIG. 5A is a plan view, and FIG. 5B is a cross-sectional view taken along the line R31-R32 of region R3 of FIG. 5A.

Referring to FIGS. 5A and 5B, the insulating layer 23 is formed on the substrate 20, the source 21a, the channel layer 22, and the drain 21b by depositing an insulating material. The insulating layer 23 may be formed of Si oxide, Si nitride, or other insulating materials.

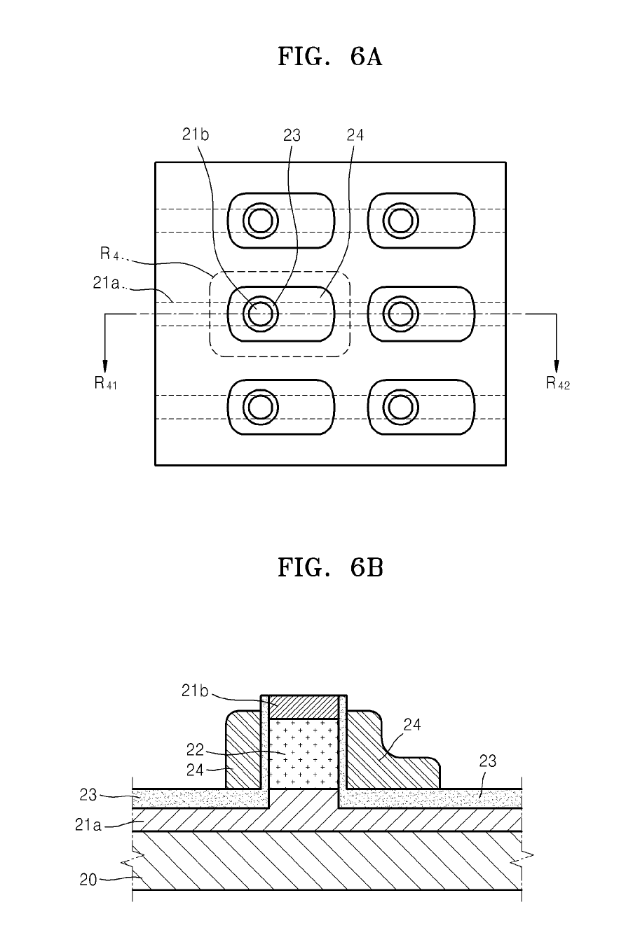

FIGS. 6A and 6B are drawings showing an example of a process of forming the gate electrode 24. FIG. 6A is a plan view, and FIG. 6B is a cross-sectional view taken along the line R41-R42 of region R4 of FIG. 6A.

Referring to FIGS. 6A and 6B, after forming a conductive material layer on the insulating layer 23 on which the drain 21b is formed, the gate electrode 24 is formed by using a patterning process and a surface of the drain 21b is exposed. Through the process described above, the gate electrode 24 may be formed as an all-around type to surround lateral sides of a portion of the source 21a, the channel layer 22, and the drain 21b. In this way, the source 21a, the channel layer 22, and the drain 21b are vertically formed with respect to the upper surface of the substrate 20 and the gate electrode 24 is formed in a type to surround the peripheral region of the channel layer 22 to maximize an area of a corresponding region between the gate electrode 24 and the channel layer 22, and thus, the gate control is readily realized.

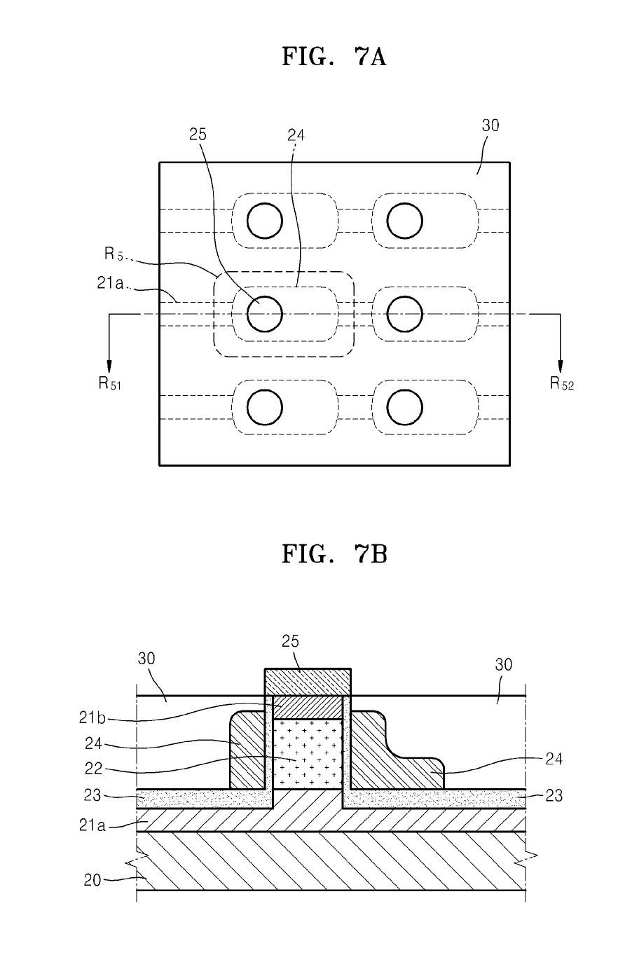

FIGS. 7A and 7B are drawings showing an example of a process of forming the first ILD film 30 and the resistive memory layer 25. FIG. 7B is a cross-sectional view taken along the line R51-R52 of region R5 of FIG. 7A.

Referring to FIGS. 7A and 7B, the first ILD film 30 is formed by forming an insulating material layer on the insulating layer 23 and the gate electrode 24. Next, the resistive memory layer 25 is formed on the exposed drain 21b by using a material having a variable resistance characteristic. The first ILD film 30 may be formed of a silicon oxide, a nitride oxide, or other insulating materials. The resistive memory layer 25 is formed of a transition metal oxide or an oxide having a perovskite structure on a region of the drain 21b.

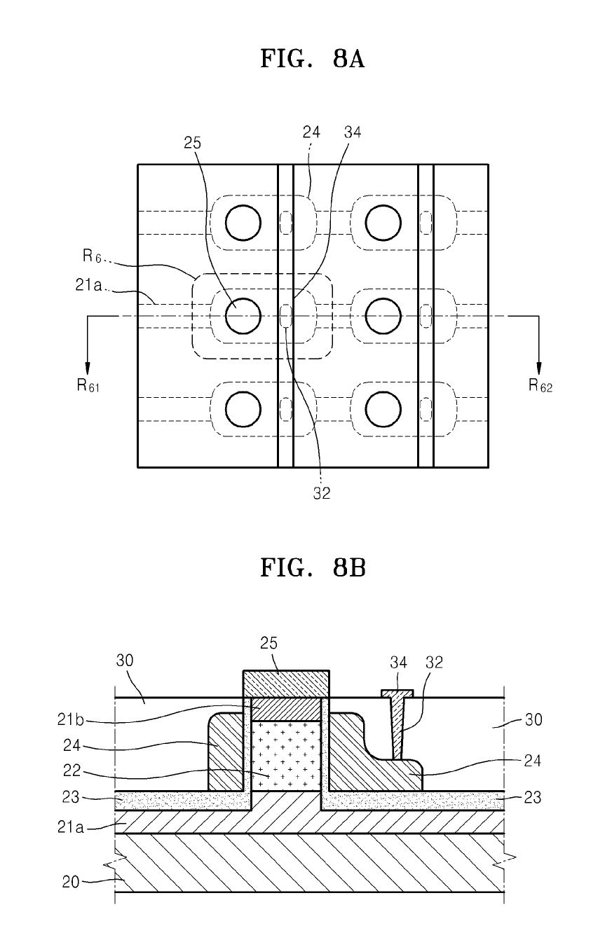

FIGS. 8A and 8B are drawings showing an example of a process of forming the word line 34 through which power may be applied to the gate electrode 24. FIG. 8B is a cross-sectional view taken along the line R61-R62 of region R6 of FIG. 8A. Referring to FIGS. 8A and 8B, a portion of the gate electrode 24 is exposed by forming a hole in the first ILD film 30 that corresponds to the gate electrode 24. Next, the first contact layer 32 is formed by filling the hole formed in the first ILD film 30 with a conductive material, and the word line 34 formed in a particular direction is formed on the first ILD film 30.

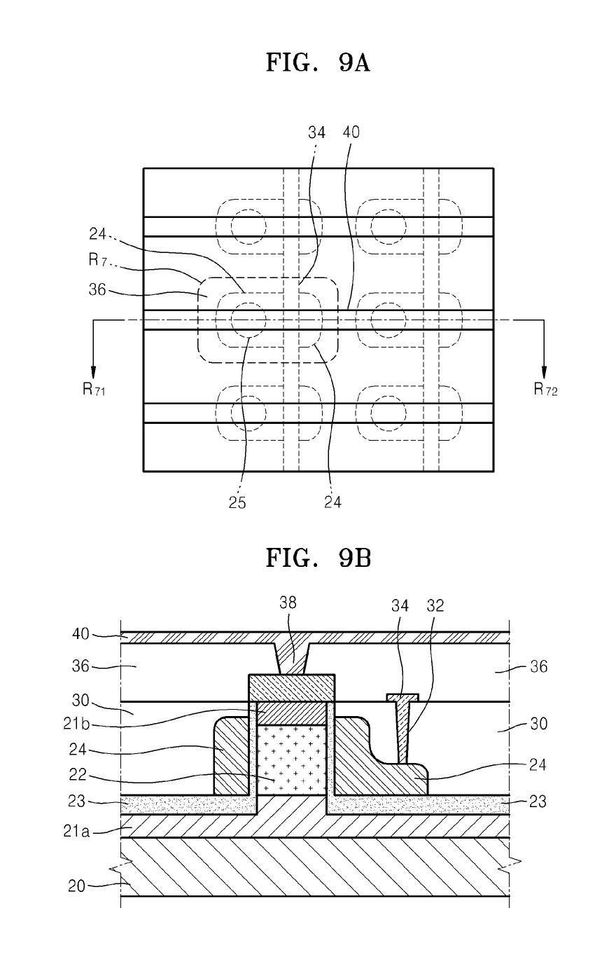

FIGS. 9A and 9B are drawings showing an example of a process of forming the bit line 40 through which power may be applied to the resistive memory layer 25. FIG. 9B is a cross-sectional view taken along the line R71-R72 of region R7 of FIG. 9A.

Referring to FIGS. 9A and 9B, a second ILD film 36 is formed on the first ILD film 30, the resistive memory layer 25, and the word line 34 by forming an insulating material layer. The second ILD film 36 may be formed of a silicon oxide, a silicon nitride, or other insulating materials. Next, a hole is formed in the second ILD film 36 that corresponds to the resistive memory layer 25. After forming the second contact layer 38 by filling the hole formed in the second ILD film 36 with a conductive material, the bit line 40 is formed on the second ILD film 36.

The bit line 40 may have a direction that is the same as or different from that of the word line 34, for example, may have a direction perpendicular to that of the word line 34. In FIG. 9A, the bit line 40 is formed to have a direction that is the same as that of the source 21a and is formed to be perpendicular to the word line 34, but the present invention is not limited thereto.

As depicted in FIG. 9A, the resistive memory device 100 described above may be formed on a plurality of regions of the substrate 20, and may constitute a resistive memory array that includes a plurality of resistive memory devices 100 by using the word line 34 and the bit line 40 as common electrodes.

According to the present invention, a gate electrode having a shape surrounding a channel is included in the resistive memory device 100, and thus, further effective gate control may be realized. Also, a vertical type 1T(transistor)-1R(resistance) memory device structure is provided by sequentially forming a source, a channel layer, a drain, and a resistive memory layer in a direction perpendicular to an upper surface of a substrate, and thus a short channel effect may be prevented.

Example embodiments having thus been described, it will be obvious that the same may be varied in many ways. Such variations are not to be regarded as a departure from the intended spirit and scope of example embodiments, and all such modifications as would be obvious to one skilled in the art are intended to be included within the scope of the following claims.

What is claimed is:

1. A resistive memory device comprising:
a source, a channel layer, a drain, and a resistive memory layer configured vertically on a substrate;
a gate electrode configured around the channel layer; and
an insulating layer between the channel layer and the gate electrode.

2. The resistive memory device of claim 1, wherein the source, the channel layer, the drain, and the resistive memory layer are configured sequentially on an upper surface of the substrate.

3. The resistive memory device of claim 1, wherein the source, the channel layer, the drain, and the resistive memory layer are configured vertically on upper surface of the substrate.

4. The resistive memory device of claim 1, wherein the resistive memory layer includes a bipolar resistance variable material.

5. The resistive memory device of claim 1, wherein the resistive memory layer includes a transition metal oxide.

6. The resistive memory device of claim 5, wherein the transition metal oxide is formed of at least one selected from the group consisting of Ni oxide, Ti oxide, Hf oxide, Zr oxide, Zn oxide, W oxide, Co oxide, Al oxide and Nb oxide.

7. The resistive memory device of claim 1, wherein the resistive memory layer is formed of at least one selected from the group consisting of PrCaMnO(PCMO), CaMnO3(CMO), CaTiO3, BaTiO3, SrTiO3, KTaO3, KNbO3, and NaNbO3.

8. The resistive memory device of claim 1, wherein the gate electrode is configured to completely surround the channel layer.

9. A resistive memory array comprising a plurality of the resistive memory devices of claim 1.

10. The resistive memory array of claim 9, further comprising:
a word line configured to carry signals to the gate electrode; and
a bit line configured to carry signals to the resistive memory layer.

11. The resistive memory array of claim 10, further comprising:
a first interlayer dielectric (ILD) film between the gate electrode and the word line; and
a first contact layer between the gate electrode and the word line.

12. The resistive memory array of claim 10, further comprising:
a second ILD film between the resistive memory layer and the bit line; and
a second contact layer between the resistive memory layer and the bit line.

13. The resistive memory array of claim 9, wherein the resistive memory layer includes a bipolar resistance variable material.

14. A method of manufacturing a resistive memory device, comprising:
forming a source, a channel layer, and a drain sequentially stacked on a substrate;
forming a gate electrode around the channel layer; and
forming a resistive memory layer on the drain.

15. The method of claim 14, wherein the source, the channel layer, and the drain are sequentially formed in a vertical direction on an upper surface of the substrate.

16. The method of claim 14, wherein
the source, the channel layer, and the drain are formed by etching a source region, a channel region, and a drain region, and
the source region, the channel layer, and the drain are formed using dopants.

17. The method of claim 16, wherein the channel region is doped with a dopant having a first conductivity type the source and drain regions are doped with a dopant having a second conductivity type.

18. The method of claim 14, further comprising:
forming a first ILD film on the gate electrode; and
forming a word line to be used to carry signals to the gate electrode on the first ILD film.

19. The method of claim 14, further comprising:
forming a second ILD film on the resistive memory layer; and
forming a bit line to carry signals to the resistive memory layer on the second ILD film.

20. The method of claim 14, wherein forming the gate electrode includes forming the gate electrode to completely surround the channel layer.
